(19) United States
(12) Patent Application Publication
(10) Pub. No.: US 2024/0184185 A1
(43) Pub. Date: Jun. 6, 2024

(54) AN APPARATUS, SYSTEM AND METHOD OF COOLING SENSITIVE ELECTRONICS IN A HEATED ENVIRONMENT

(71) Applicant: JABIL INC., St. Petersburg, FL (US)

(72) Inventors: Dennis Scott Prows, St. Petersburg, FL (US); Gerry Willard Degraaf, St. Petersburg, FL (US); Ewaryst Zygmunt Polch, St. Petersburg, FL (US)

(21) Appl. No.: 18/559,894

(22) PCT Filed: May 11, 2022
(86) PCT No.: PCT/US2022/028722

§ 371 Date: Nov. 9, 2023

Related U.S. Application Data
(60) Provisional application No. 63/186,979, filed on May 11, 2021.

(51) Int. Cl. G03B 17/55; H05K 7/20

(52) U.S. Cl. CPC G03B 17/55; H05K 7/20145

(57) ABSTRACT

An apparatus, system and method of cooling sensitive electronics in a heated environment. The apparatus, system and method include the sensitive electronics adjacent to a heating chamber, and within an electronics chamber; a flow separator axially extending through the electronics chamber; and an air intake that flows air external to the heating chamber and electronics chamber into the electronics chamber axially to the flow separator, such that the flow forms a thermal break zone adjacent the heating chamber on one side of the flow separator, and a cooling zone on an other side of the flow separator about the sensitive electronics.

### CROSS-REFERENCE TO RELATED APPLICATIONS

This application is a national stage application of International Patent Application No. PCT/US2022/028722, filed May 11, 2022, entitled “AN APPARATUS, SYSTEM AND METHOD OF COOLING SENSITIVE ELECTRONICS IN A HEATED ENVIRONMENT”, which claims the benefit of priority to U.S. Provisional Application No. 63/186,979, filed May 11, 2021, entitled “AN APPARATUS, SYSTEM AND METHOD OF COOLING SENSITIVE ELECTRONICS IN A HEATED ENVIRONMENT”, the entirety of which is incorporated herein by reference as if set forth in its entirety.

### BACKGROUND

### Field of the Disclosure

The disclosure is directed to electronic devices and, more particularly, to an apparatus, system and method of cooling sensitive electronics in a heated environment.

### Description of the Background

Electronics generally have thermal limits, for both storage and use. This fact notwithstanding, it is becoming increasingly desirable in the modern era to have sensitive electronics, such as chip-set camera technologies, operating in high heat environments.

By way of example, in Internet-of-Things (IOT) systems, including an oven or a stovetop, it is becoming increasingly desirable to include optical electronics, such as camera assemblies, in a high-heat system. By way of example, an IoT system may implement an artificial intelligence (AI) into the cooking process, wherein the AI monitors the cooking process and automatically implements a rules hierarchy to ensure well-cooked food, and part of this rules hierarchy may be different parallel cooking paths based on a “visual” monitoring of the food as it cooks-thereby necessitating that the IoT system includes a camera system. This may particularly be the case where the previous manual viewing methods, such as the front glass in the door of an oven, are being eliminated, such as for cost or safety purposes.

However, operation of sensitive electronics in a high heat environment, such as in an oven, does not comport with the aforementioned typical limitations on such sensitive electronics. Accordingly, the need exists for a new apparatus, system and method for cooling sensitive electronics in high heat environments.

### SUMMARY OF THE DISCLOSURE

The disclosure is directed to and includes an apparatus, system and method of cooling sensitive electronics in a heated environment. The apparatus, system and method include the sensitive electronics adjacent to a heating chamber, and within an electronics chamber; a flow separator axially extending through the electronics chamber; and an air intake that flows air external to the heating chamber and electronics chamber into the electronics chamber axially to the flow separator, such that the flow forms a thermal break zone adjacent the heating chamber on one side of the flow separator, and a cooling zone on an other side of the flow separator about the sensitive electronics.

### BRIEF DESCRIPTION OF THE DRAWINGS

The disclosed non-limiting embodiments are discussed in relation to the drawings appended hereto and forming part hereof, wherein like numerals indicate like elements, and in which:

FIG. 1 illustrates aspects of the embodiments:

FIG. 2 illustrates aspects of the embodiments: and

FIG. 3 illustrates aspects of the embodiments.

### DETAILED DESCRIPTION

The figures and descriptions provided herein may have been simplified to illustrate aspects that are relevant for a clear understanding of the herein described apparatuses, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, for the sake of brevity a discussion of such elements and operations may not be provided herein. However, the present disclosure is deemed to nevertheless include all such elements, variations, and modifications to the described aspects that would be known to those of ordinary skill in the art.

Embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure. Nevertheless, it will be apparent to those skilled in the art that certain specific disclosed details need not be employed, and that embodiments may be embodied in different forms. As such, the embodiments should not be construed to limit the scope of the disclosure. As referenced above, in some embodiments, well-known processes, well-known device structures, and well-known technologies may not be described in detail.

The terminology used herein is for the purpose of describing particular embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

When an element or layer is referred to as being “on”, “engaged to”, “connected to” or “coupled to” another element or layer, it may be directly on, engaged, connected or coupled to the other element or layer, or intervening elements or layers may be present, unless clearly indicated otherwise. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). Further, as used herein the term “and/or” includes any and all combinations of one or more of the associated listed items.

Yet further, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the embodiments.

In order to cool sensitive electronics, such as optical, i.e., camera, electronics, in high heat environments, the embodiments use external air to move heat through and away from the area of the sensitive electronic assembly(ies). By way of non-limiting example in relation to an oven, it is typical that the oven wall generates significant radiant heat from inside the interior cavity to just outside the cavity, even given the insulating techniques known in the art. This radiant heat eventually and substantially heats adjacent electronic assemblies, even if those sensitive electronics are outside the cooking cavity, thereby causing sensitive electronics, such as optical electronics, to fail.

By way of example, an oven may include an optical chipset which, when used in conjunction with a controller storing a plurality of rules, analyze for food recognition, and doneness in light of the recognized food. This optical chipset (i.e., camera, image processing, hardware, firmware, software) may be very sensitive to the heat produced within the very oven being sensed. To address this sensitivity, the embodiments provide a cooling system for these sensitive electronics.

Consequently, a multi-zone cooling zone is provided in the embodiments, in the area(s) of an oven (or similar heating appliance or storage area) which the sensitive electronics reside. The providing of the multi-zone cooling enables the use of lower cost electrical components (as there is no or a lessened need to use heat-resistant components), and simplifies appliance construction (as there is no need to substantially insulate the area around the sensitive electrical components). Accordingly, manufacturing efficiencies are enhanced by the embodiments, and construction and design costs are decreased.

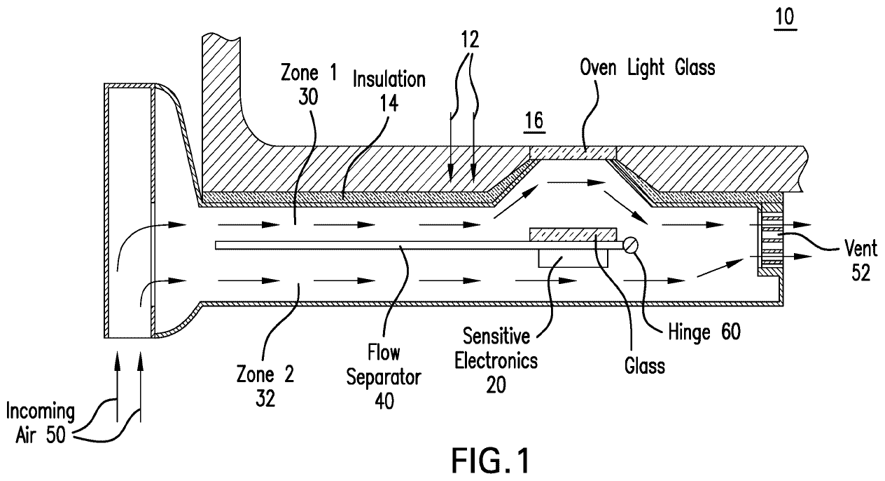

More specifically, and as illustrated in FIG. 1, the embodiments provide a cooling system 10 capable of preventing radiant heat 12 from overwhelming the insulation 14 in a heating chamber 16 and thereby adversely affecting the operation and life expectancy of sensitive electronics 20 at the outer perimeter of or adjacent to the heating chamber 16. The cooling system 10 may include multiple zones 30, 32, such that one zone 30 may provide moving air as an insulating barrier to the radiant heat, and a second zone 32 may provide a cooling zone to maintain a desired temperature of the sensitive electronics.

Zone 1 30 uses moving air as an insulative barrier that creates a thermal break which disrupts the radiant heat coming from the oven cavity as that heat radiates towards the sensitive electronics. This thermal break provides a region of low thermal conductivity that reduces or substantially prevents the flow of thermal energy between the heating chamber and the region of the device in which the sensitive electronics reside.

Zone 2 32 uses the same moving air to inject fresh, cool air onto and adjacent to the sensitive electronics, such as the referenced optical, i.e., camera, electronics. Zone 2 provides a temperate environment in which the sensitive electronics are protected within their acceptable operating range and “dormant” range.

The cooling air 32 of zone 2 may be separated from is the more heated insulative air 30 of zone 1 by a flow separator 40. The flow separator 40 may be any element that separates a single incoming flow 50 into two or more partial flows.

The flow separator 40 may be a solid device, such as a heat resistance and/or heat insulating slab of a sufficient physical depth to separate the incoming flow 50 into the zone 1 and the zone 2 as discussed. By way of example, the solid separator may be formed of glass or plastic. A venting 52 of the incoming air may also be provided, such as at the same side of the electronics chamber for the incoming air in a full circulatory circuit embodiment, at the opposite side of the chamber from the incoming air in a flow-through embodiment, or at both sides of the electronics chamber. Needless to say, the venting 52 may flow to one or more chimneys that carry away waste/hot flow, or the flow may be carried away from the venting 52 and/or the cooler air be redirected over the sensitive electronics prior to exiting the chamber via any other means known to the skilled artisan.

A solid flow separator may be mechanically actuated, such as solely during manufacture or during operation, to obtain a desired flow. By way of example and as shown, one side of the flow separator, such as on the side opposing the incoming air, may have an opening for flow-through, and/or may be hinged 60, such as a positionally locking hinge that may be suitably locked, permanently or temporarily, when the desired position of the flow separator is reached. Alternatively, the flow separator may be hinged on the side thereof more proximate to the incoming air. Likewise, the flow separator may be mounted to the electronics assembly, and thus may additionally include one or more heat sinks for the electronics assembly.

Simply put, an adjustable flow separator, whether manually or automatically adjustable, may modify the air flow within the electronics chamber. By way of non-limiting example, a positional change in the flow separator may introduce turbulence and/or otherwise interrupt or redirect the laminar flow in zone 1 or zone 2, such as so as to move the heat break farther from the sensitive electronics, or to increase the volume of cool air present about the sensitive electronics, with respect to the air flow in the electronics chamber. That is, the sir flow may be modified to improve the “cooling envelope” immediately round the sensitive electronics.

By way of additional example of presenting a modified airflow within the electronics chamber, a rounded surface may be provided at an opposing end of the electronics chamber from the incoming air, such that the incoming flow initially passes adjacent to the heating chamber to provide zone 1, and then rounds the far end of the chamber to provide an opposing exit flow. That is, a physical barrier or waveguide may be presented within or by one or may faces of the electronics chamber so as to guide the laminar flow along a particular path, and/or so as to introduce turbulence to the laminar flow to produce the desired flow of hot and cold air.

In any such an embodiment, air may be vented at the same side of the chamber as the incoming air for fully circulated air, and/or at the opposite end of the chamber from the incoming air so as to remove any air heated in the heat break. The latter vent may be placed gravimetrically “above” the rounded surface, to take advantage of the fact that the heated air should form the upper part of the air flow upon heating in zone 1. Of course, the skilled artisan will appreciate, in light of the instant disclosure, that air may be passed through, partially recirculated, fully recirculated, and/or fully circulated in ones of the embodiments discussed herein, and may be vented accordingly, so as to improve the cooling envelope around the sensitive electronics.

In alternative embodiments, the flow separator may be non-solid, such as the introduction of laminar or turbulent flow around the area of the sensitive electronics. Similarly, an air jet may be introduced from the opposing end of the chamber from the incoming air, central to the electronics chamber, to thereby provide a turbulent air break in the incoming air flow, i.e., a flow separator.

In each such embodiment, the air may be vented from either side or both sides of the electronics chamber. For example, the air may be vented from the same side of the chamber as the incoming air, and from the opposite side of the chamber, so as to remove the heated air from the thermal break zone prior to flow past the electronics, in a full circulatory embodiment; or from the opposing side of the chamber from the incoming air in a fully flow-through embodiment for both zones.

Accordingly, a controller may control the actuation of the flow separator and/or of the airflow. The controller may preferably be electronic in nature, and may be remotely communicative with the controlled system. By way of example, the controller may control the airflow and/or the flow separator responsive to sensing, such as temperature sensing in or adjacent to the heating chamber and/or the sensitive electronic region.

As referenced throughout, the zones may result from an incoming air flow. In a preferred embodiment, this incoming air flow may constitute forced air, such as may produce a flow rate sufficient to maintain the necessary insulative and environmental maintenance conditions discussed throughout. This forced air may be produced by any methodology apparent to the skilled artisan in light of the discussion herein, such as by an axial fan aimed axially planar to the flow separator.

As is additionally discussed throughout, the incoming air flow may be vented, such as from either side or both sides of the sensitive electronics chamber. This venting may occur actively, such as via one or more vent fans, or may occur passively, such as wherein the venting occurs responsively to the pressure produced at the incoming flow, and/or the division of the flow by the flow separator.

The sensitive electronics, as used herein, may include a sensitive electronic device or chipset, such as an optical and/or imaging device/chipset, as well as necessary secondary elements that operate in conjunction with the sensitive electronics, such as storage elements, processing elements, communication elements, and the like. The “operating environment”, as used herein, may refer to the lowest temperature of all such devices that is needed for proper operation.

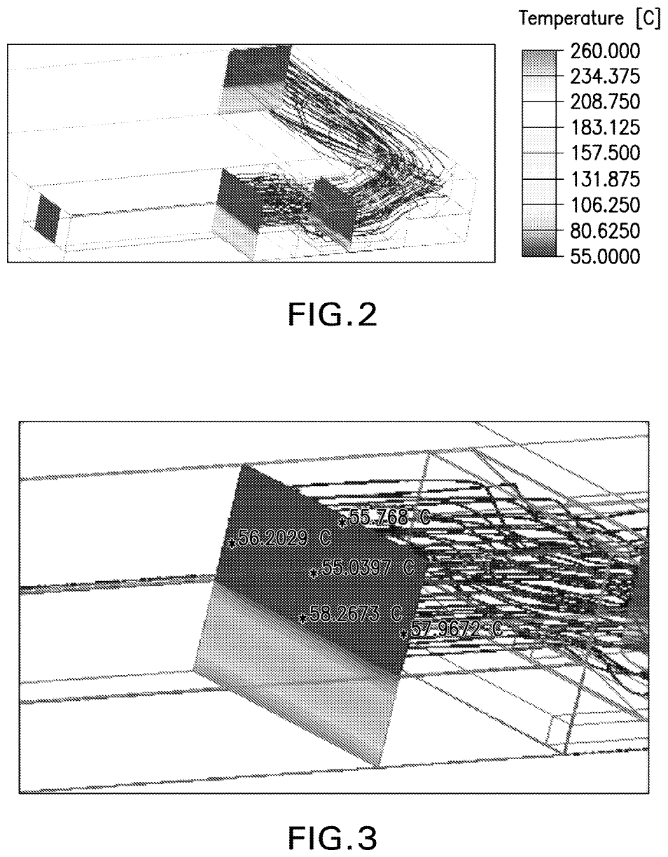

FIGS. 2 and 3 illustrate temperature simulations for the embodiment illustrated in FIG. 1. More particularly, the temperature simulations show how the flow separation effectively provides cool air to the electronics unit, and provides a heat break that maintains the hot air in zone 1.

FIG. 3 illustrates that the hot/radiant surface (shown in orange) loses heat across the thermal break of zone 1. A more dramatic change in temperature occurs at the flow separator, which then enables the cool temperature in the cooling chamber of zone 2.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

What is claimed is:

1. A cooling system for sensitive electronics, comprising:
the sensitive electronics adjacent to a heating chamber, and within an electronics chamber;
a flow separator axially extending through the electronics chamber; and
an air intake that flows air external to the heating chamber and electronics chamber into the electronics chamber axially to the flow separator, such that the flow forms a thermal break zone adjacent the heating chamber on one side of the flow separator, and a cooling zone on an other side of the flow separator about the sensitive electronics.

2. The cooling system of claim 1, wherein the sensitive electronics are optical electronics.

3. The cooling system of claim 2, wherein the optical electronics comprise a camera system.

4. The cooling system of claim 1, wherein the heating chamber comprises an oven chamber.

5. The cooling system of claim 1, wherein the thermal break zone provides a region of low thermal conductivity that reduces or substantially prevents thermal energy from reaching the flow separator.

6. The cooling system of claim 1, wherein the flow separator separates the flow into two or more partial flows.

7. The cooling system of claim 6, wherein the partial flows on either side of the flow separator are uni-directional.

8. The cooling system of claim 6, wherein the partial flows on either side of the flow separator are in opposing directions.

9. The cooling system of claim 1, wherein the flow separator comprises a solid element.

10. The cooling system of claim 9, wherein the solid element comprises one of glass or plastic.

11. The cooling system of claim 9, wherein the solid element is mechanically actuated.

12. The cooling system of claim 11, wherein the mechanically actuation includes a hinge.

13. The cooling system of claim 1, wherein the flow separator is non-solid.

14. The cooling system of claim 13, wherein the non-solid flow separator comprises a laminar or turbulent flow.

15. The cooling system of claim 13, wherein the non-solid flow separator comprises an air jet.

16. The cooling system of claim 1, further comprising a vent from which the flow exits the electronics chamber.

17. The cooling system of claim 1, wherein the air intake comprises an axial fan.
